(19) United States
(12) Patent Application Publication
(10) Pub. No.: US 2012/0280602 A1
(43) Pub. Date: Nov. 8, 2012

(54) Mobile Electronic Device Cabinet

(76) Inventor: James F. Baker, Lititz, PA (US)

(21) Appl. No.: 13/462,775

(22) Filed: May 2, 2012

Related U.S. Application Data
(60) Provisional application No. 61/481,579, filed on May 2, 2011.

(51) Int. Cl. H05K 5/02; H05K 7/20

(52) U.S. Cl. 312/236; 312/237

(57) ABSTRACT

The cabinet may house electronic devices and be constructed with a top, a base, opposing side walls, and front and rear doors hingedly mounted on the opposing side walls. A plurality of drawers may extend between and be slidably mounted on the side walls. Each of the drawers may have a gap on each side near the rear wall. The gaps are intended to receive electric cords that connect to the electronic devices in the drawer. Power strips may be mounted on rear portions of the cabinet side walls. An unobstructed space may extend between the power strips and the gaps in each of the drawers for housing the electric cords and to provide access to the rear walls of the drawers.

### RELATED APPLICATION

This nonprovisional patent application claims the benefit of U.S. Provisional Application No. 61/481,579 filed May 20, 2011 and entitled “Mobile Electronic Device Cart”.

### BACKGROUND

The present mobile electronic cabinet relates to commercial storage furniture and more particularly to those adapted to hold mobile electronic devices such as cell phones, smart phones, tablets, MP3's, netbooks, notebooks, Ipads and the like

Conventional cabinets that are used to hold electronic devices, particularly those intended to hold tablets, netbooks and notebooks, store the equipment in an edgewise position, like a book. It is believed that this design causes excessive wear and tear on a tablets and their exposed components. The devices may move back and forth in transit, thereby leaving the screen vulnerable to scratching. Small devices like a smart phone, eReader or iPod might fall through or get lost between vertical dividers.

### SUMMARY

The present cabinet is adapted to house electronic devices and is constructed with a top, a base, opposing side walls, front and rear doors hingedly mounted on the opposing side walls. A plurality of drawers extending between and slidably mounted on said opposing side walls, each of said drawers having a bottom, front and rear walls and first and second sides and a power strip connectable to an electric outlet, that improvement which comprises:

### BRIEF DESCRIPTION OF THE DRAWINGS

FIG. 1 is a front view of an exemplary embodiment of the present cabinet;

FIG. 2 is an enlarged front view of the cart with the front door open and the drawers partially drawn outwardly;

FIG. 3 is an enlarged rear view of the cart with the rear door open;

FIG. 4 is an enlarged rear view of a portion of one of the drawers; and

FIG. 5 is an enlarged top view of a portion of one of the drawers.

### DETAILED DESCRIPTION OF AN EXEMPLARY EMBODIMENT

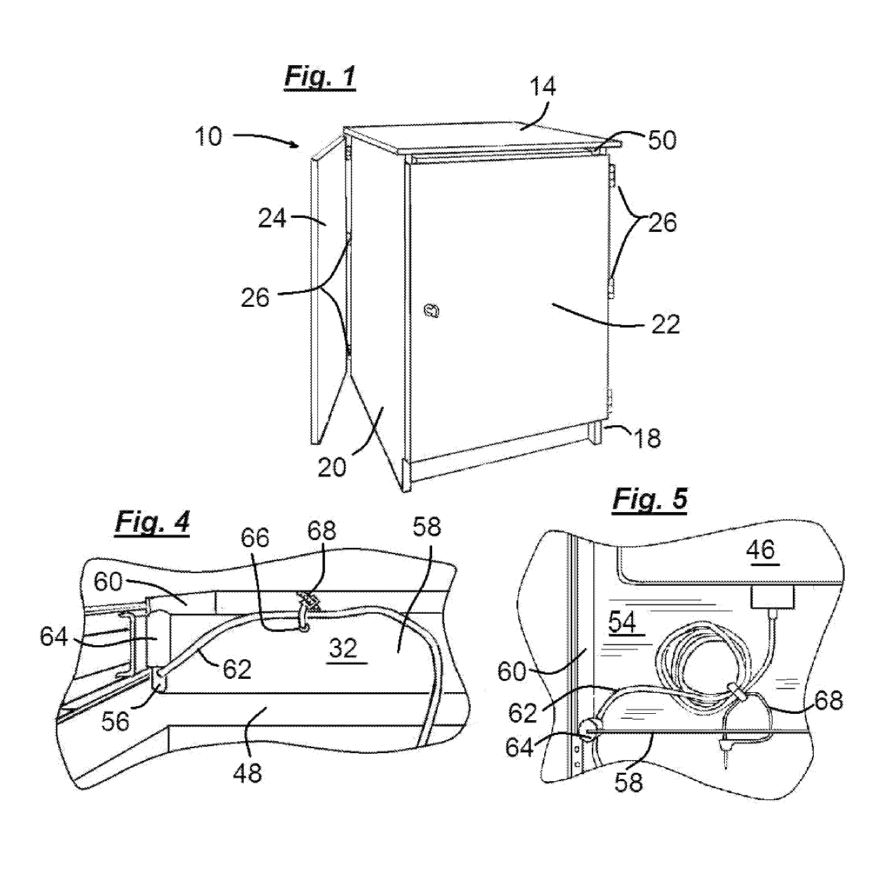

As illustrated in FIGS. 1-3, the mobile cabinet, generally designated 10, may be constructed with a top 14, a base 16, opposing side walls 18, 20 and front and rear doors 22, 24 mounted by hinges 26 to the opposing side walls. Caster wheels 28, 30 may be mounted on the base and extend below the side walls to provide mobility. A plurality of drawers 32 may be slidably mounted on and extend between the side walls.

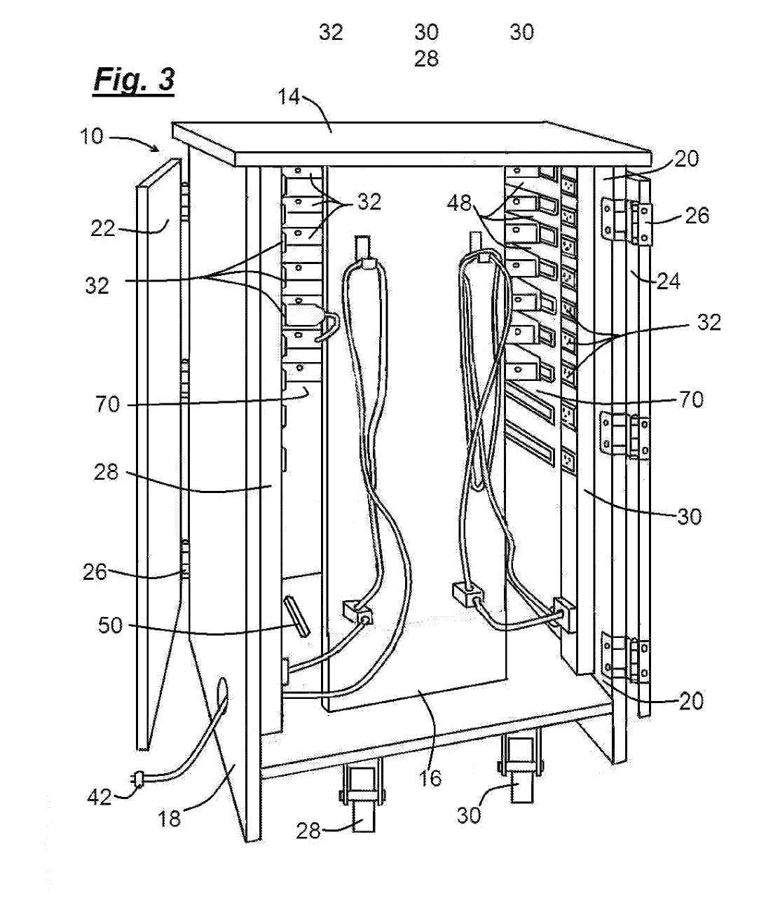

The mobile cabinet 10 may be equipped with features that enhance its usefulness for housing electronic devices. As illustrated in FIG. 3, surge protectors or simple power strips 28, 30 equipped with multiple electric sockets 32 may be mounted on rear portions of the side walls. Electric cables 34, 36 may be connected via intermediate junction boxes 38, 40 to the power strips. Plugs 42, 44 may be attached to free ends of the cables for coupling with an electric outlet (not shown).

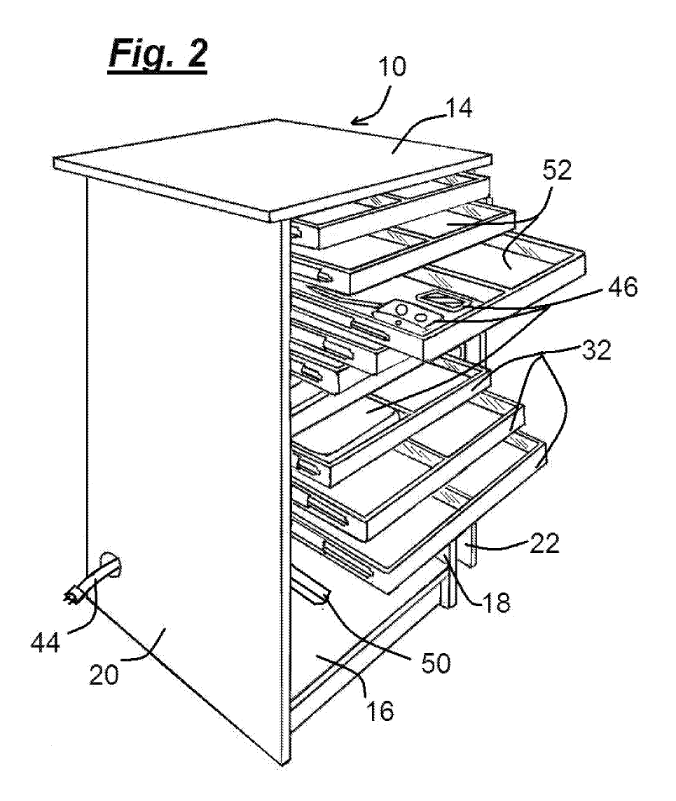

As illustrated in FIG. 2, the drawers 32 may be particularly well adapted to store electronic devices 46. The depth of the drawers 32 may be approximately equal to the thickness of a standard size laptop computer, and a space 48 (FIGS. 3, 4) may be provided between each of the drawers to accommodate thicker devices. Likewise, the area of each of the drawer bottoms 52 may be large enough for the electronic devices to lie flat. In addition to the spaces between the drawers, one or more vents 50 may extend through the base 16 and between the upper edges of the front and rear doors and the top of the cabinet (FIG. 1). In this manner, heat generated during the charging process may flow out of the cabinet. A pad 54 (FIG. 5) may be placed on the bottom of each of the drawers to cushion the electronic device 46 and keep it from shifting position.

As illustrated in FIGS. 4 and 5, gaps 56 may be provided between a rear wall 58 and the opposing sides 60 of each of the drawers 32. The gap 56 may receive an electric cord 62 that is connectable to at least one of the electronic devices 46. A plug 64 may be mounted on the rear wall of the drawer to hold the cord in place. One or holes 66 may be formed in the rear wall to receive a tie 68 to provide additional immobilization to the cord.

As illustrated in FIG. 3, unobstructed spaces 70 may be provided between the rear walls of the drawers adjacent to the gaps and the power strips. These spaces may house the electric cords and may be sufficient for a user to attach the electric cords to the rear walls of said drawers and to the power strip.

1. In a cabinet adapted to house electronic devices, said cabinet being constructed with a top, a base, opposing side walls, front and rear doors hingedly mounted on the opposing side walls, a plurality of drawers extending between and slidably mounted on said opposing side walls, each of said drawers having a bottom, front and rear walls and first and second sides and a power strip connectable to an electric outlet, that improvement which comprises:
each of said drawers having a gap between the rear wall and at least one of the sides, said gap being sized to receive an electric cord connectable to at least one of the electronic devices;
said power strip being mounted on a rear portion of one of the side walls of the cabinet; and
an unobstructed space between the power strip and a portion of the rear wall adjacent to the gap on each of said drawers for housing the electric cords.

2. The cabinet according to claim 1, wherein said unobstructed space is sufficient for a user to attach the electric cords to the rear walls of said drawers and to the power strip.

3. The cabinet according to claim 1, wherein a second gap is provided between the rear wall and the second side of each of the drawers.

4. The cabinet according to claim 3, wherein a second power strip is mounted on the opposing side wall and a second unobstructed space extends between said second power strip and a portion of the rear wall adjacent to the second side of each of the drawers.

5. The cabinet according to claim 1, wherein a plug is mountable in the gap in each of the drawers above the electric cord.

6. The cabinet according to claim 1, wherein a vent is provided between the top of said cabinet and each of the front and rear doors.

7. The cabinet according to claim 6, wherein at least one vent is provided in the base of said cabinet.

8. The cabinet according to claim 1, wherein the depth of each drawer is approximately equal to the thickness of a laptop computer.

9. The cabinet according to claim 1, wherein a plurality of wheeled casters are mounted on the base of said cabinet.
